(19) United States
(12) Patent Application Publication
(10) Pub. No.: US 2006/0113604 A1
(43) Pub. Date: Jun. 1, 2006

(54) Methods for reduced circuit area and improved gate length control

(75) Inventors: Howard Lee Tigelaar, Allen, TX (US); Antonio Luis Pacheco Rotondaro, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/000,715

(22) Filed: Dec. 1, 2004

(51) Int. Cl. H01L 23/52; H01L 21/4763

(52) U.S. Cl. 257/368; 438/586; 438/620; 257/773

(57) ABSTRACT

Semiconductor devices (102) are presented along with fabrication methods (202) therefor, in which a conductive contact structure (116b) is formed with a lower contact surface (116c) having a lateral contact dimension (152), where the contact structure (116b) is at least partially coupled with a contact landing surface of a polysilicon structure (110) having a lateral contact landing surface dimension (150) that is less than about 140% of the lateral contact dimension (152) of the conductive contact structure (116b).

### FIELD OF INVENTION

The present invention relates generally to semiconductor devices and more particularly to methods and structures for reducing circuit area and improving gate length control in the fabrication of semiconductor devices.

### BACKGROUND OF THE INVENTION

In the manufacture of semiconductor device products such as integrated circuits, individual electrical components are formed on or in a semiconductor substrate, and are thereafter interconnected to form electrical circuits. Interconnection of these components within a semiconductor device is typically accomplished by forming a multi-level interconnect network structure in layers formed over the electrical components, sometimes referred to as metalization, by which the device active elements are connected to other devices to create the desired circuits. Individual wiring layers within the multi-level network are formed by depositing an insulating or dielectric layer over the discrete devices or over a previous interconnect layer, and patterning and etching openings for vias and/or trenches. Conductive material, such as copper or tungsten is then formed in the openings to form inter-layer contacts and interconnect routing structures.

FIGS. 1A-1C illustrate a portion of a conventional semiconductor device 2, including a semiconductor body (e.g., a silicon wafer) 4, and shallow trench isolation (STI) structures 8, where transistors are formed on or in the semiconductor body 4 including source/drains 6 and gates 10 that are disposed above channel regions of the semiconductor body 4 between the source/drains 6, where the gates 10 have sidewall spacers 11 formed on the lateral sides thereof. The interconnection structure initially includes conductive silicide structures 7 formed on the upper surfaces of transistor source/drains 6 and gates 10, with a pre-metal dielectric (PMD) material 14 formed over the transistors. Contact openings are then etched through the PMD material 14 and conductive material 16 such as tungsten (W) is formed in the openings to provide electrical coupling to the transistor terminals, including source/drain contacts 16a and gate contacts 16b. Thereafter, further dielectric layers are formed with conductive (e.g., copper Cu) interconnect routing structures to interconnect the various components to form an integrated circuit. In FIGS. 1A-1C, one such metalization level is illustrated, comprising a first inter-layer or inter-level dielectric (ILD) material 24 with copper structures 26 formed therein, where a diffusion barrier 25 is formed beneath and laterally of the copper 26 to inhibit diffusion of copper material into the ILD 24.

As illustrated in FIG. 1A, the connection to the transistor gate structures 10 is made outside of the active regions (source/drains 6) of the semiconductor body 4, wherein conventional design rules provide for minimum separation distance between the gate contacts 16b and the active regions 6. In coupling the tungsten contacts 16b to the transistor gate terminals 10, moreover, current design rules require that the polysilicon structure 10 be much larger than the opening for the contact 16b at the coupling location, to minimize contact resistance by ensuring that the entire lower surface of the gate contact 16b is situated over the silicide 7 of the gate 10, even where misalignment errors occur. As illustrated in FIGS. 1A and 1B, the polysilicon gate structures 10 have a relatively narrow gate length dimension 54 within the active regions 6, where the gate length 54 is determined according to the desired transistor performance and lithography limitations. As illustrated in FIGS. 1A and 1C, however, the polysilicon structures 10 are fanned out (e.g., widened) to a length 50 to provide relatively long contact landing surfaces outside the active regions 6 for coupling with the gate contacts 16b that have a length 52. This widening of the polysilicon 10 facilitates lowered contact resistance and serves to accommodate any misalignment of the contacts 16b with the polysilicon 10, such that all of the lower surface of the contacts 16b is coupled with the polysilicon 10 or the silicide 7 thereof.

However, the wider polysilicon contact regions limit efforts to scale the circuit area in the device 2 and make fabrication more difficult. In particular, the transition of the polysilicon 10 from the gate length dimension 54 to the larger contact landing surface dimension 50 needs to be spaced from the active regions 6 to avoid reflective notching and poly flaring that can cause dimensional variations in the length of the gate 10. Conventional design rules specify that the polysilicon length transition must be spaced at least 550 Å (55 nm) from the edge of the active regions 6 to avoid or mitigate these reflective notching and poly flaring effects. Furthermore, the provision of wider polysilicon contact landing surfaces increases the spacing between adjacent active regions 6. For example, conventional design rules specify addition of 600 Å (60 nm, e.g., 30 nm on either side) to the contact dimension 52 to account for possible misalignment of the contact 16b to the polysilicon 10, resulting in the contact landing dimension 50 being at least 1500 Å (150 nm) for a contact 16b having a length 52 of 900 Å (90 nm). Thus, the minimum contact landing surface dimension 50 is about 67% larger than the contact dimension 52 in conventional semiconductor devices 2.

As a result, the active-to-active region spacing 60 (FIG. 1A) includes the upper poly flaring spacing (55 nm)+the upper additional polysilicon length (30 nm)+the contact length 52 (90 nm)+the lower additional polysilicon length (30 nm)+the lower poly flaring spacing (55 nm) for a total active-to-active region spacing 60 of about 260 nm (2600 Å). In addition, efforts to reduce the spacing (pitch) 62 between adjacent polysilicon lines 10 are limited by the enlarged contact landing surface dimensions 50. For example, where the design rule specifies a minimum distance of 120 nm between adjacent polysilicon structures 10, the pitch distance 62 (measured between the centers of the gates 10) includes a left half of the contact length dimension (45 nm)+an additional polysilicon length (30 nm)+the minimum spacing distance (120 nm)+another additional polysilicon length (30 nm)+a right half of the contact length dimension (45 nm) for a total pitch spacing 62 of 270 nm (2700 Å).

In addition to limiting the ability to scale the circuit area, optical proximity correction (OPC) techniques must be used to tailor the corners at the transition from the contact landing pad to the poly gate length, wherein generation of the mask used to pattern the polysilicon 10 is more difficult, causing more variation in gate critical dimensions (gate CD's). Thus, there is a need for improved semiconductor device structures and fabrication methods therefor by which the circuit area can be reduced while improving control over the critical transistor gate length dimensions.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. The primary purpose of the summary is rather to present some concepts of the invention in a simplified form as a prelude to the more detailed description that is presented later.

The present invention relates to semiconductor devices and fabrication techniques in which landing surfaces for gate structures or other component structures are made to be smaller than allowed by conventional design rules relative to the dimension of the conductive contact, whereby circuit area can be reduced while improving control over the critical transistor gate length dimensions.

One aspect of the invention provides a semiconductor device, comprising an electrical component with a polysilicon structure formed above a semiconductor body, where the polysilicon structure has a contact landing surface with a lateral contact landing surface dimension. The device further comprises a conductive contact structure comprising a lower contact surface with a lateral contact dimension. All or a portion of the lower contact surface is coupled with at least a portion of the contact landing surface of the polysilicon structure, where the lateral contact landing surface dimension is less than about 140% of the lateral contact dimension of the conductive contact structure. In one implementation, the lateral contact landing surface dimension of the polysilicon structure is less than or equal to the lateral contact dimension of the conductive contact structure, such as substantially equal to the lateral contact dimension of the conductive contact structure, or in another implementation, smaller than the lateral contact dimension of the conductive contact structure.

The electrical component may be a transistor, where the polysilicon structure is a gate structure having a first gate portion with a lateral gate length dimension above an active region of the semiconductor body, and a second gate portion including the contact landing surface spaced from the active region. In this case, the lateral gate length dimension may be substantially equal to the lateral contact landing surface dimension, by which the complexity of additional OPC and reflective notching may be mitigated or avoided.

Another aspect of the invention provides a semiconductor device, comprising a MOS transistor with a source formed on a first lateral side of a channel region in a semiconductor body, and a drain formed on a second opposite lateral side of the channel region in the semiconductor body. The transistor further comprises a gate structure including first and second portions, where the first portion is situated above the channel region to form a transistor gate and having a lateral gate length dimension, and the second portion is coupled with the first portion and includes a contact landing surface with a lateral contact landing surface dimension. The device further comprises a conductive contact structure formed above the second portion, the conductive contact structure having a lower contact surface with a lateral contact dimension at least partially in contact with the contact landing surface, wherein the lateral contact landing surface dimension is less than about 140% of the lateral contact dimension.

Still another aspect of the present invention provides a method of fabricating a semiconductor device. The method comprises forming an electrical component having a polysilicon structure situated above a semiconductor body, where the polysilicon structure has a contact landing surface with a lateral contact landing surface dimension. The method further comprises forming a conductive contact structure having a lower contact surface at least partially coupled with the contact landing surface of the polysilicon structure, where the lower contact surface has a lateral contact dimension, and where the lateral contact landing surface dimension of the polysilicon structure is less than about 140% of the lateral contact dimension of the conductive contact structure.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIG. 1A is a partial top plan view in section illustrating a portion of a conventional semiconductor device in which polysilicon gate structures are fanned out according to current design rules to provide enlarged contact landing surfaces for coupling with tungsten contacts;

FIGS. 1B and 1C are partial side elevation views in section illustrating polysilicon active and contact regions taken along lines 1B-1B and 1C-1C, respectively, in the device of FIG. 1A;

FIG. 2A is a partial top plan view in section illustrating a portion of an exemplary semiconductor device wherein gate structures and contact landing surfaces thereof remain shorter than the contact dimension in accordance with one or more aspects of the invention and where there is no corner near the transistor region that would require additional OPC;

FIGS. 2B and 2C are partial side elevation views in section illustrating polysilicon active and contact regions taken along lines 2B-2B and 2C-2C, respectively, in the device of FIG. 2A;

FIGS. 2D-2F are partial side elevation views in section illustrating polysilicon contact regions with several exemplary lateral contact surface dimensions in accordance with the invention taken along lines 2D-2D, 2E-2E, and 2F-2F, respectively, in the device of FIG. 2A;

FIG. 3 is a flow diagram illustrating an exemplary semiconductor device fabrication method in accordance with the invention; and

FIGS. 4A-4F are partial side elevation views in section illustrating polysilicon active and contact regions in the device of FIG. 2A undergoing fabrication processing at several different points in a fabrication process flow.

### DETAILED DESCRIPTION OF THE INVENTION

The present invention will now be described with reference to the attached drawings, in which like reference numerals are used to refer to like elements, wherein the illustrated structures are not necessarily drawn to scale. The invention relates to semiconductor devices and fabrication methods therefor, in which narrow contact landing surfaces are provided on polysilicon or other type gate structures in order to facilitate semiconductor device fabrication and circuit area reduction, while improving control over critical gate length dimensions in active regions of the device.

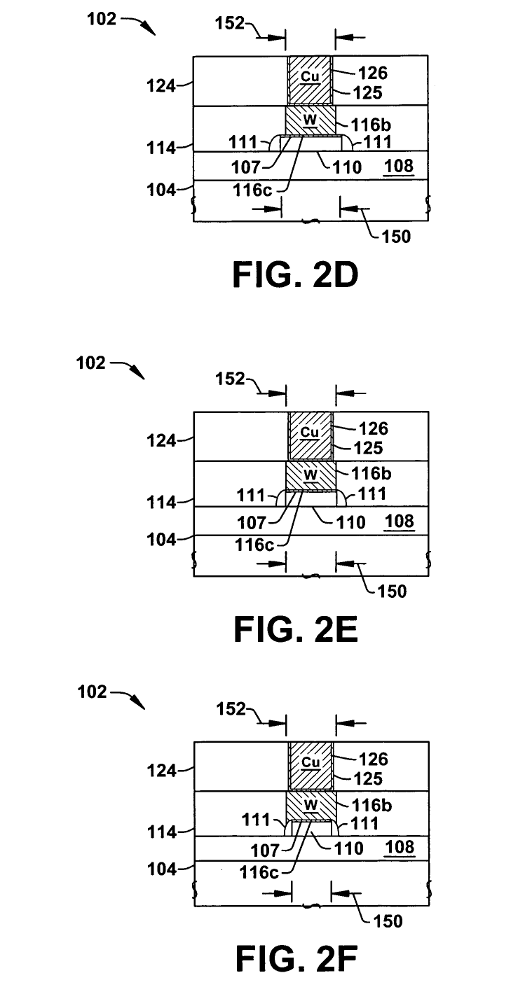

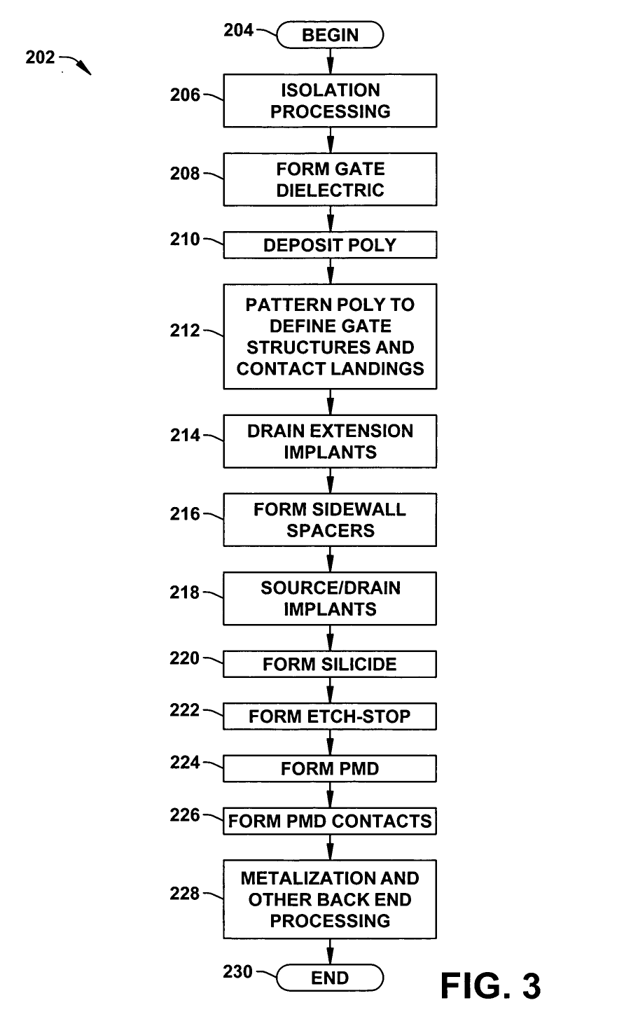

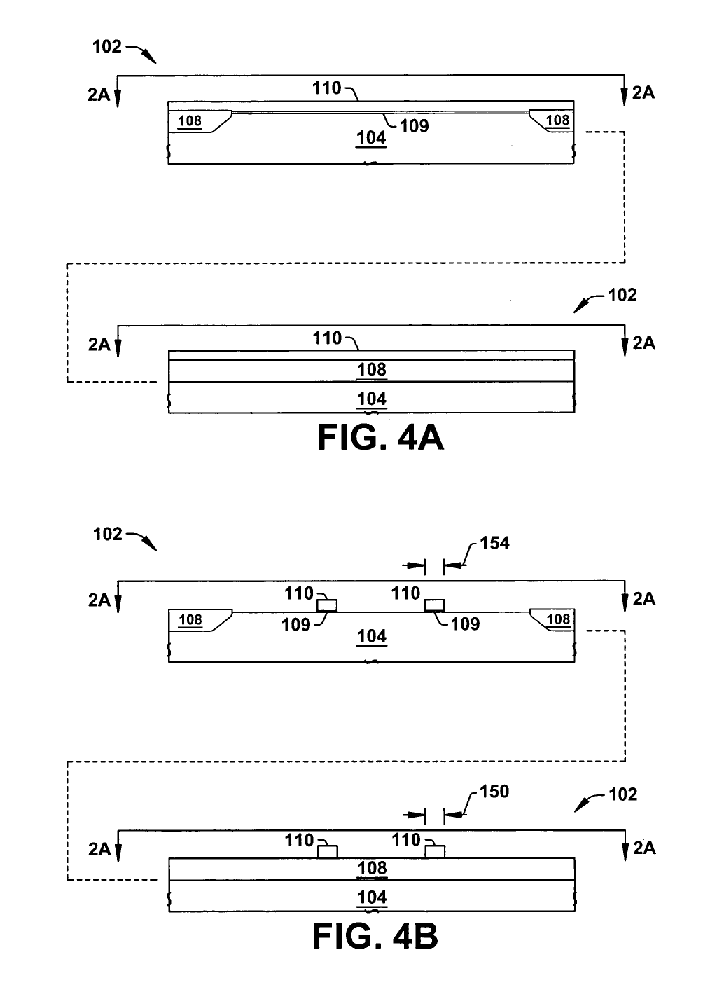

An exemplary semiconductor device 102 is illustrated in FIGS. 2A-2F in accordance with one or more aspects of the present invention. The device 102 comprises a semiconductor body (e.g., a silicon wafer) 104, and shallow trench isolation (STI) structures 108 formed therein. Transistors are formed on or in the semiconductor body 104 including source/drains 106 and gates 110 disposed above channel regions of the semiconductor body 104 between the source/drains 106, where the gates 110 have sidewall spacers 111 formed on the lateral sides thereof. Any type of semiconductor body 104 may be used, including but not limited to silicon wafers, SOI wafers, or other forms or types of semiconductor body 104. Also, any type of isolation structures 108 may be employed, including but not limited to STI structures or field oxide structures formed using local oxidation of silicon (LOCOS) techniques.

Although illustrated in the context of polysilicon gate structures 110, the invention may be carried out in association with metal gates, or transistor gates formed of any conductive materials, wherein contact landing surfaces of the gate structures are provided with lateral dimensions that are less than the minimum dimensions of conventional design rules. Furthermore, the invention may be employed in forming connections to other polysilicon or conductive structures, whether such structures are part of a transistor gate or other type of electrical component or electrical terminal or connection point thereof, wherein all such alternative implementations are contemplated as falling within the scope of the present invention and the appended claims.

Silicide 107 is formed on the upper surfaces of transistor source/drains 106 and of the gates 110, and a thin contact etch stop layer (not shown in FIGS. 2A-2F) is formed over the silicide 107, followed by a PMD dielectric 114 formed over the transistors. Contact openings are then etched through the PMD material 114 stopping on the etch stop layer. The contact etch chemistry is then changed to etch through the contact etch stop layer with little penetration into the PMD 114 or silicide layer 107. Tungsten (W) or other conductive material 116 is then formed in the PMD openings to create the contacts 116a and 116b for electrical coupling to the transistor source/drain and gate terminals, respectively. The device 102 includes further metalization levels, one of which is illustrated in FIGS. 2A-2F, including a first inter-layer or inter-level dielectric (ILD) material 124 with copper structures 126 formed therein. A diffusion barrier 125 is formed beneath and laterally of the copper 126 to inhibit diffusion of copper material into the ILD 124, wherein the device wafer is typically planarized using chemical mechanical polishing (CMP) following deposition of the copper 126 before proceeding to the next metalization layer or level. The initial PMD layer and subsequent metalization layers illustrated and described herein are merely examples, wherein other interconnect structures, forms, and materials may be employed within the scope of the invention.

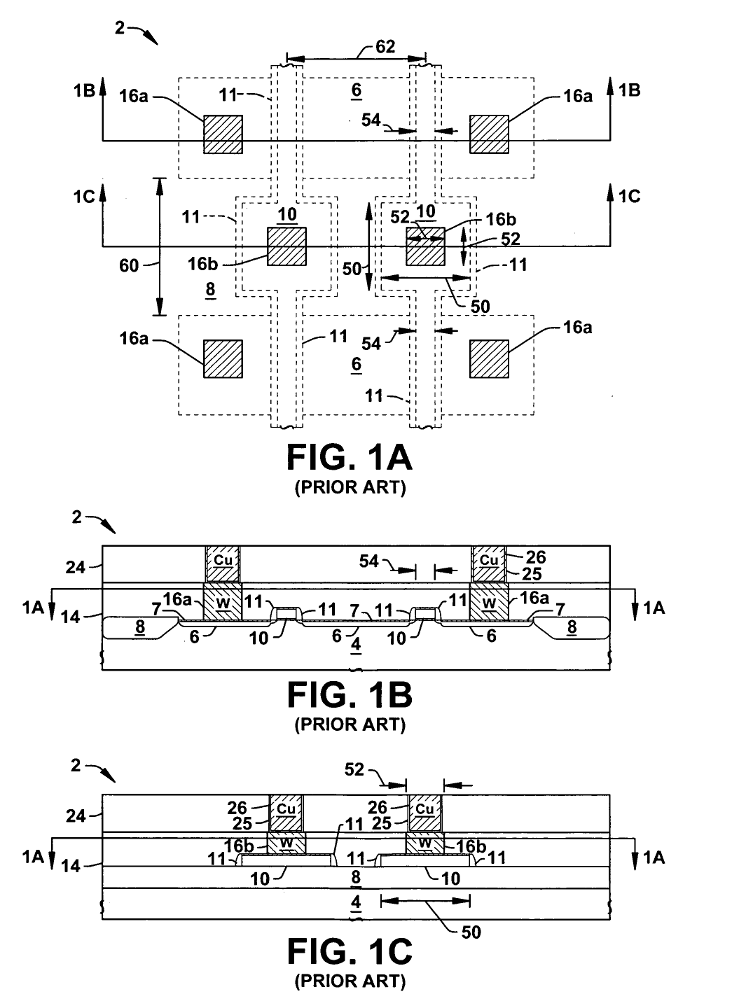

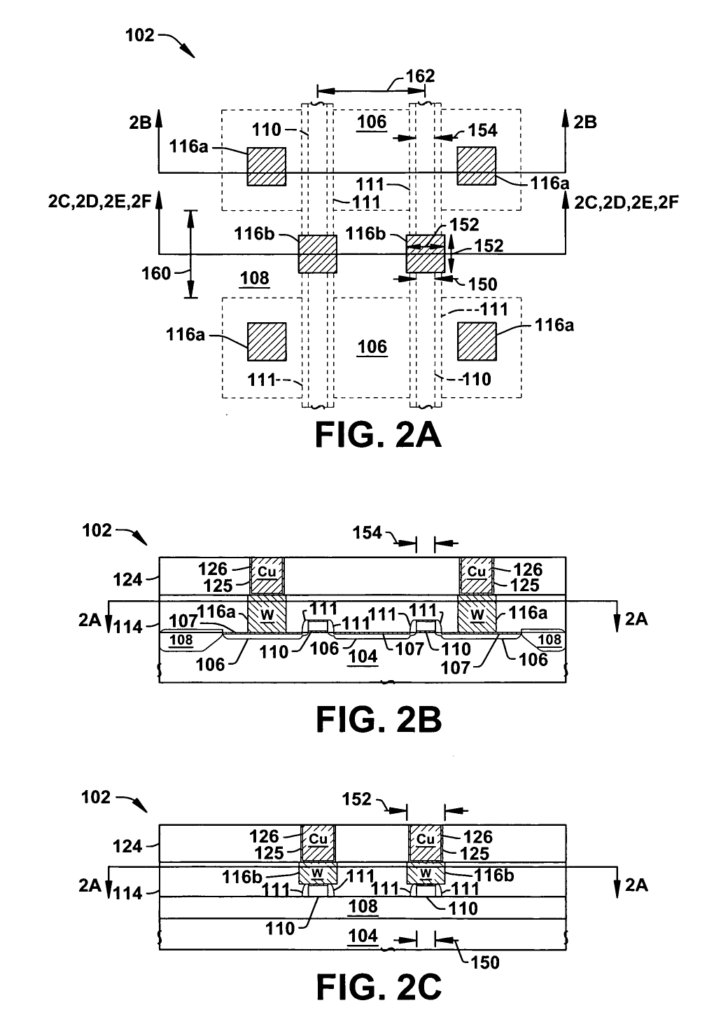

As illustrated in FIG. 2A, the connection of the PMD contacts 116b to the transistor gate structures 110 is made outside of the active regions (e.g., the tungsten gate contacts 116b are spaced from the source/drains 106). The conductive contact structures 116b have a lateral contact length dimension 152 (e.g., about 90 nm in the exemplary device 102), as shown in FIGS. 2A and 2C. As previously discussed, the conventional design rules required that the polysilicon be flared out to a longer lateral size for such connections, where the lateral contact landing surface dimension of the polysilicon structure was more than about 67% larger than the lateral contact dimension of the conductive contact structure (e.g., as in the device 2 of FIGS. 1A-1C above).

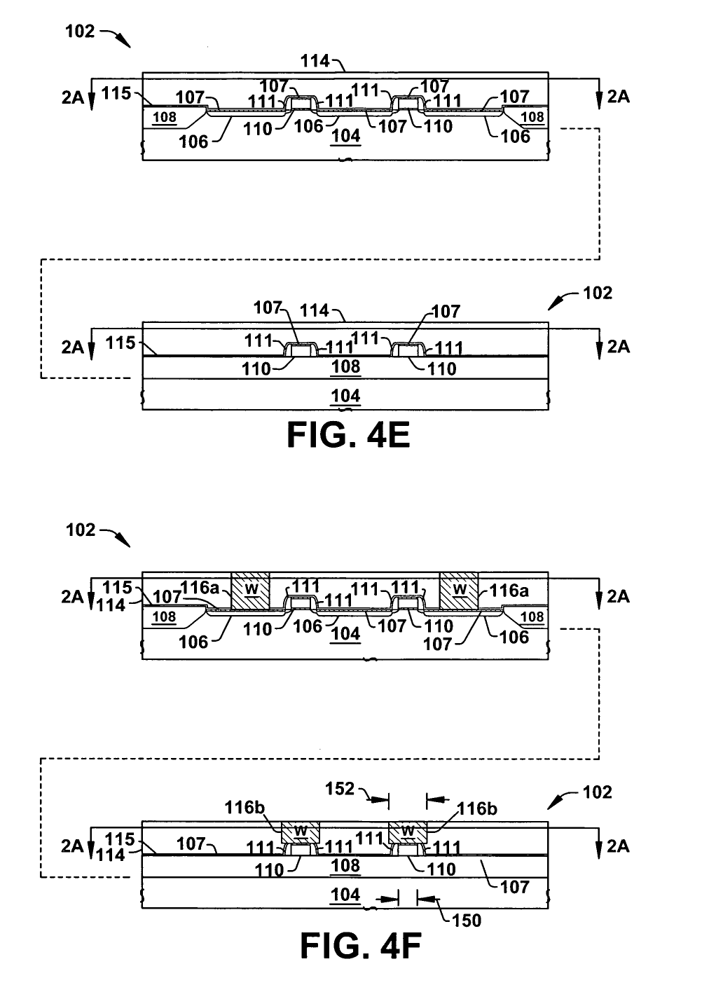

In contrast, the device 102 in FIGS. 2A-2F comprises polysilicon gate structures 110 that are of essentially constant length (no flaring for contact landings), whereby no OPC is required to pattern corners in the polysilicon near the gates 110, no reflective notching or poly flaring effects are seen in patterning the gates 110, and the area occupied by each transistor is reduced. In particular, the exemplary polysilicon structures 110 each include a first gate portion that operates as a transistor gate near the active regions 106 with a lateral gate length dimension 154 (FIGS. 4A and 4B) and a second portion including a contact landing surface to interface with the gate contact 116b, where the contact landing surface is spaced from the active regions 106 and has a lateral contact landing surface dimension 150 that is less than about 140% of the lateral contact dimension 152 of the contact structure 116b.

In the exemplary implementation of FIGS. 2A-2F, the lateral gate length dimension 154 is substantially equal to the lateral contact landing surface dimension 150 (no dimensional flaring) whereby no reflective notching problems are seen, and wherein no special OPC is required for the gate structures 110, although this is not a strict requirement of the invention. Other implementations are possible with the polysilicon contact landing dimension 150 being less than about 140% of the dimension 152 of the contact 116 (FIGS. 2A and 2C), wherein the dimensions 150 and 154 may be the same or different, and wherein some flaring or dimensional variation along the gate structure 110 may be provided, wherein all such variant implementations are contemplated as falling within the scope of the present invention and the appended claims.

FIG. 2D illustrates one possible implementation of the device 102, in which the polysilicon contact landing dimension 150 is larger than the contact dimension 152, but is nevertheless less than 140% of the dimension 152. Other possible implementations are illustrated in FIGS. 2E and 2F, wherein the lateral contact landing surface dimension of the polysilicon structure is less than or equal to the lateral contact dimension of the conductive contact structure. In the example of FIG. 2E, the lateral contact landing surface dimension 150 is substantially equal to the lateral contact dimension 152, and in FIG. 2F, the lateral contact landing surface dimension 150 of the polysilicon structure 110 is less than the lateral dimension 152 of the contact 116b.

The invention may be employed in making contact to gate structures of any material, wherein the invention is not limited to polysilicon gate structures or polysilicon structures. In general, an aspect of the invention provides semiconductor devices having MOS transistors with a gate structure comprising a first portion situated above the channel region to form a transistor gate and having a lateral gate length dimension, and a second portion coupled with the first portion, the second portion including a contact landing surface with a lateral contact landing surface dimension, as well as a conductive contact structure formed above the second portion, where the conductive contact structure has a lower contact surface with a lateral contact dimension at least partially in contact with the contact landing surface, and where the lateral contact landing surface dimension is less than about 140% of the lateral contact dimension.

Furthermore, as stated above, the invention is not limited to connecting transistor gate structures, but may be employed in coupling a conductive contact structure to any polysilicon structure in a semiconductor device. Thus, while the illustrated device 102 comprises an array-like configuration of transistors with gates of more than one transistor being coupled to one another, the invention is not limited to the illustrated implementations.

The reduction of the contact landing surfaces relative to the contact structure dimension may tend to decrease the amount of contact area between the gate contact 116b and the polysilicon 110 (or the silicide 107 thereof), resulting in a net increase in the contact resistance. However, the increased contact resistance is less detrimental for low power gate contacts and other low power connections. Furthermore, the contacts 116b can in some situations be made longer in the transverse lateral direction to compensate for any contact resistance increase resulting from the reduced length-wise dimension of the polysilicon landing surface structure. Moreover, the alignment of the contacts gate 116b to the polysilicon 110 can be controlled using typical lithography techniques such that the entire contact landing surface of the polysilicon contact landings (or the silicide thereof) is in contact with the lower contact surface 116c of the gate contacts 116b (FIGS. 2D-2F), wherein the invention may be advantageously employed with little or no adverse impact on the circuit performance (particularly for low current connections), while allowing scaling of the circuit area together with improved control of critical transistor gate length dimensions.

Comparing the exemplary device 102 in FIG. 2A with the conventional device in FIG. 1A, it is noted that the invention facilitates reduction in both the lateral dimensions (e.g., the active-to-active region spacing and the polysilicon-to-polysilicon pitch spacing directions), whereby scaling of transistor circuit area is facilitated in the device 102 generally. For example, the elimination of the extra polysilicon around the gate contacts 116b in FIG. 2A results in reduced active-to-active region spacing 160 (contact dimension 152 (90 nm)+2 times the contact-to-active region spacing (2×55 nm)=200 nm (2000 Å)) compared with the larger spacing 60 (260 nm) in the conventional device 2 of FIG. 1A. In this regard, it may be possible to further reduce the active-to-contact spacing requirement below 55 nm (e.g., below the active-to-poly corner spacing conventionally required to avoid or mitigate reflective notching or poly flaring effects). The exemplary device 102 also achieves reduced circuit area in the pitch-spacing direction, wherein the pitch spacing 162 includes just the contact length 152 (90 nm) and the poly-to-poly minimum spacing (120) nm for a total dimension 162 of about 210 nm (2100 521 ), which is less than the spacing 62 (270 nm) in FIG. 1A.

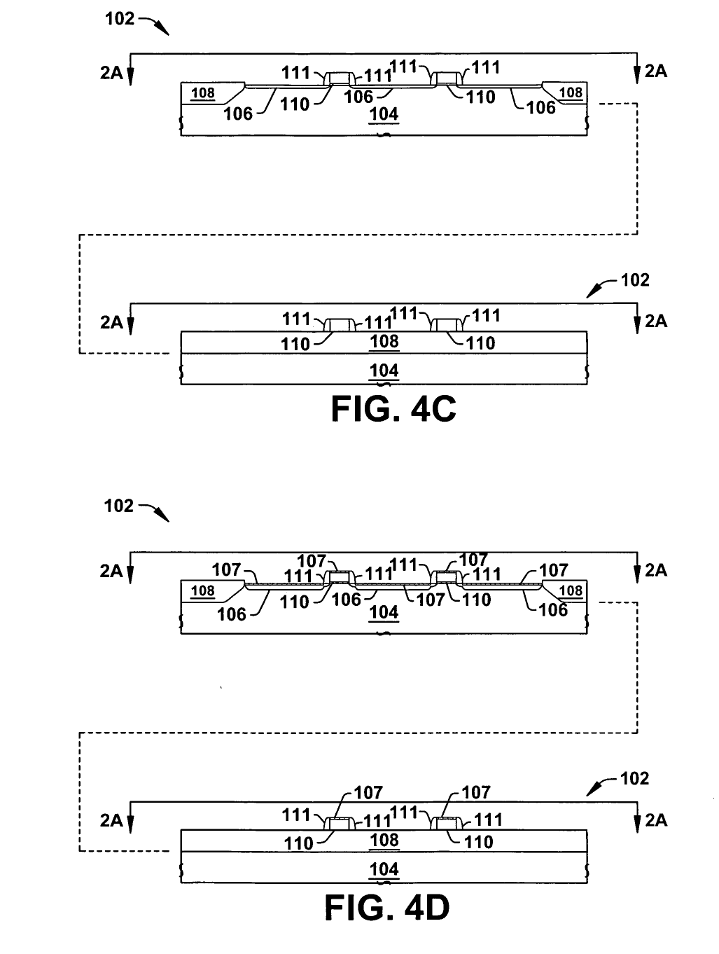

Referring also to FIGS. 3 and 4A-4F, the invention further provides methods for fabricating a semiconductor device, such as the device 102, in which a conductive contact structure 116b is formed with a lower contact surface 116c having a lateral contact dimension 152, and the contact 116b is at least partially coupled with a contact landing surface of a polysilicon structure 110 having a lateral contact landing surface dimension 150 that is less than about 140% of the lateral contact dimension 152. FIG. 3 illustrates one exemplary method 202 in accordance with the invention, and FIGS. 4A-4F illustrate the polysilicon active and contact regions of the exemplary device 102 undergoing fabrication processing at several different points in a fabrication process flow.

Although the exemplary method 202 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated.

Referring initially to FIGS. 3 and 4A, the method 202 begins at 204, wherein isolation and other initial processing (e.g., well formation, etc.) is performed at 206. The upper portion (e.g., partial section) of FIG. 4A illustrates an active portion of the device 102 (e.g., along line 2B-2B in FIG. 2A above) and the lower portion of FIG. 4A shows a contact region between adjacent active regions 106 in the device 102 (e.g., along line 2C-2C in FIG. 2A), wherein shallow trench isolation processing has been performed to create the isolation structures 108 in the semiconductor body 104.

Thereafter, an electrical component (e.g., a MOS transistor) is formed at 208-218 in FIG. 3 (FIGS. 4A-4D) having a polysilicon gate structure 110 situated above the semiconductor body 104, where the polysilicon 110 includes a contact landing surface with a lateral contact landing surface dimension 150 that is less than about 140% of the lateral contact dimension of a subsequently formed conductive contact 116b in accordance with the invention. At 208 in the method 202, a gate dielectric is formed (thin gate oxide 109 in FIG. 4A), and a layer of polysilicon 110 is deposited at 210 over the gate dielectric (e.g., polysilicon 110 in FIG. 4A). Alternatively, other multilayer gate materials may be deposited at 210, such as polysilicon 110, metals, or stacks or combinations thereof, to form a conductive gate electrode above the gate dielectric 109.

Referring also to FIG. 4B, the polysilicon 110 is then patterned at 212 using any suitable photolithographic masking and etching techniques, to form the patterned polysilicon gate structures 110 and contact landings thereof. In the exemplary device 102, for example, the polysilicon structures 110 comprise first portions proximate the active regions 106 (FIG. 2A) that will operate as transistor gates in the finished device 102, as well as second portions spaced from the active regions 106 that include contact landing surfaces for coupling with the subsequently formed tungsten contacts 116.

As seen in FIG. 4B, the exemplary polysilicon structures 110 patterned at 212 have a first portion with a gate length dimension 154 (upper section of FIG. 4B) and a second portion with a lateral contact surface dimension 150 (lower section of FIG. 4B), where the contact landing dimension is less than about 140% of the lateral contact dimension 152 (FIG. 2A) of the subsequently formed contact 116b in accordance with the invention. In the illustrated implementation, moreover, the gate length and contact landing surface dimensions 154 and 150 are substantially equal, although this is not a strict requirement of the invention.

The patterning and masks employed at 212 may be adjusted according to specific values for the dimensions 150 and 154 in accordance with the invention. Relative to the eventual contact dimension 152, the patterning at 212 may be such that the lateral contact landing surface dimension of the polysilicon structure can be made less than or equal to the lateral contact dimension of the conductive contact structure. In one example (e.g., FIG. 2E above) the polysilicon 110 is patterned at 212 such that the dimensions 150 and 152 are substantially equal, and in another possible implementation (FIG. 2F above), the patterning at 212 provides a patterned polysilicon structure 110 where the lateral contact landing surface dimension 150 is less than the lateral contact dimension 152 of the subsequently formed conductive contact structure 116b. It is noted in the example of FIG. 4B that providing equal gate length and contact landing surface dimensions 154 and 150 mitigates the need for OPC in the polysilicon gate etch mask, and hence reduces the fabrication complexity.

Referring also to FIG. 4C, drain extension implants are then performed at 214 to initially dope shallow portions of the active regions (source/drains 106), and sidewall spacers 111 are formed at 216 along the lateral sides of the patterned polysilicon structures 110. As illustrated in FIG. 4D, deep source/drain implants are performed at 218 to further define the active region source/drains 106, and conductive metal suicide 107 is formed at 220 over the transistor source/drain and gate terminals 106 and 110, respectively, using any suitable implantation, masking, and silicidation techniques.

Referring also to FIGS. 4E and 4F, following silicidation at 220, a contact etch-stop material layer 115 is deposited for use in controlling etching of contact openings in a subsequently formed PMD material. A conductive contact structure 16b is then formed at 224 and 226 having a lower contact surface at least partially coupled with the contact landing surface of the polysilicon structure 110 (e.g., or the conductive silicide 107 thereof), where the lower contact surface has a lateral contact dimension 152 that is more than about 71% of the contact landing surface dimension 150 (e.g., the lateral contact landing surface dimension 150 is less than about 140% of the lateral contact dimension 152 of the conductive contact structure 116b). At 224, an initial dielectric (PMD) material 114 is formed over the etch-stop layer 115 and the transistors (FIG. 4E). Any suitable dielectric material 114 of any desired thickness can be employed at 224 in forming the initial PMD layer 114.

At 226, conductive contacts 116a and 116b (e.g., tungsten, polysilicon, or other conductive material) are formed through the PMD layer 114 for connection to the silicide 107 at the transistor source/drains 106 (upper portion of FIG. 4F), and to the silicide 107 on the polysilicon gate structures 110 (lower portion of FIG. 4F), respectively. In one possible implementation, a selective etch process (reactive ion etching or other suitable etch process with appropriate etch mask, not shown) is used at 226 to selectively etch portions of the PMD material 114, stopping on the thin contact etch stop layer 115. The etch chemistry is then changed to etch the contact openings through the etch stop layer 115, thereby creating openings into which tungsten (W) or other conductive material 116 is provided to create the conductive contacts 116a and 116b. The masking and PMD etching at 226 essentially establishes the size and lateral dimensions of the lower contact surface 116c of the gate contacts 116b (FIGS. 2D-2F above), wherein the contact opening size may be selected according to any suitable criteria. In this regard, the patterning of the polysilicon structures at 212 may be adjusted in setting the relationship between the polysilicon and contact dimensions 150 and 152, respectively, alone or in combination with adjustments in etching the PMD contact openings at 226. Metalization and other back end processing (not shown) is then performed at 228 to complete the device 102, and the method 202 ends at 230.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising.”

What is claimed is:

1. A semiconductor device, comprising:
an electrical component comprising a polysilicon structure formed above a semiconductor body, the polysilicon structure having a contact landing surface with a lateral contact landing surface dimension; and
a conductive contact structure comprising a lower contact surface with a lateral contact dimension, at least a portion of the lower contact surface being coupled with at least a portion of the contact landing surface of the polysilicon structure;
wherein the lateral contact landing surface dimension of the polysilicon structure is less than about 140% of the lateral contact dimension of the conductive contact structure.

2. The semiconductor device of claim 1, wherein the lateral contact landing surface dimension of the polysilicon structure is less than or equal to the lateral contact dimension of the conductive contact structure.

3. The semiconductor device of claim 2, wherein the electrical component is a transistor, wherein the polysilicon structure is a gate structure having a first gate portion with a lateral gate length dimension above an active region of the semiconductor body, and a second gate portion including the contact landing surface spaced from the active region.

4. The semiconductor device of claim 3, wherein the lateral gate length dimension is substantially equal to the lateral contact landing surface dimension.

5. The semiconductor device of claim 4, wherein the lateral contact landing surface dimension of the polysilicon structure is substantially equal to the lateral contact dimension of the conductive contact structure.

6. The semiconductor device of claim 4, wherein the lateral contact landing surface dimension of the polysilicon structure is less than the lateral contact dimension of the conductive contact structure.

7. The semiconductor device of claim 2, wherein the lateral contact landing surface dimension of the polysilicon structure is substantially equal to the lateral contact dimension of the conductive contact structure.

8. The semiconductor device of claim 2, wherein the lateral contact landing surface dimension of the polysilicon structure is less than the lateral contact dimension of the conductive contact structure.

9. The semiconductor device of claim 1, wherein the electrical component is a transistor, wherein the polysilicon structure is a gate structure having a first gate portion with a lateral gate length dimension above an active region of the semiconductor body, and a second gate portion including the contact landing surface spaced from the active region.

10. The semiconductor device of claim 9, wherein the lateral gate length dimension is substantially equal to the lateral contact landing surface dimension.

11. The semiconductor device of claim 1, wherein the lateral contact landing surface dimension of the polysilicon structure is substantially equal to the lateral contact dimension of the conductive contact structure.

12. The semiconductor device of claim 1, wherein the lateral contact landing surface dimension of the polysilicon structure is less than the lateral contact dimension of the conductive contact structure.

13. A semiconductor device, comprising:
a MOS transistor comprising:
a source formed on a first lateral side of a channel region in a semiconductor body,
a drain formed on a second opposite lateral side of the channel region in the semiconductor body, and
a gate structure comprising:
a first portion situated above the channel region to form a transistor gate and having a lateral gate length dimension, and
a second portion coupled with the first portion, the second portion including a contact landing surface with a lateral contact landing surface dimension; and
a conductive contact structure formed above the second portion, the conductive contact structure having a lower contact surface with a lateral contact dimension at least partially in contact with the contact landing surface, wherein the lateral contact landing surface dimension is less than about 140% of the lateral contact dimension.

14. The semiconductor device of claim 13, wherein the lateral contact landing surface dimension is less than or equal to the lateral contact dimension.

15. The semiconductor device of claim 13, wherein the lateral gate length dimension is substantially equal to the lateral contact landing surface dimension.

16. The semiconductor device of claim 13, wherein the lateral contact landing surface dimension is substantially equal to the lateral contact dimension.

17. The semiconductor device of claim 13, wherein the lateral contact landing surface dimension is less than the lateral contact dimension.

18. A method of fabricating a semiconductor device, the method comprising:
forming an electrical component having a polysilicon structure situated above a semiconductor body, the polysilicon structure having a contact landing surface with a lateral contact landing surface dimension; and
forming a conductive contact structure having a lower contact surface at least partially coupled with the contact landing surface of the polysilicon structure, the lower contact surface having a lateral contact dimension;
wherein the lateral contact landing surface dimension of the polysilicon structure is less than about 140% of the lateral contact dimension of the conductive contact structure.

19. The method of claim 18, wherein the lateral contact landing surface dimension of the polysilicon structure is less than or equal to the lateral contact dimension of the conductive contact structure.

20. The method of claim 18, wherein the electrical component is a transistor, wherein the polysilicon structure is a gate structure having a first gate portion with a lateral gate length dimension above an active region of the semiconductor body, and a second gate portion including the contact landing surface spaced from the active region, and wherein the lateral gate length dimension is substantially equal to the lateral contact landing surface dimension.

21. The method of claim 18, wherein the lateral contact landing surface dimension of the polysilicon structure is substantially equal to the lateral contact dimension of the conductive contact structure.

22. The method of claim 18, wherein the lateral contact landing surface dimension of the polysilicon structure is less than the lateral contact dimension of the conductive contact structure.
